(19) United States
(12) Patent Application Publication
(10) Pub. No.: US 2016/0148914 A1
(43) Pub. Date: May 26, 2016

(54) SEMICONDUCTOR PACKAGE AND METHOD OF MANUFACTURING THE SAME

(71) Applicant: Samsung Electro-Mechanics Co., Ltd., Suwon-si (KR)

(72) Inventors: Chang Sup SONG, Suwon-si (KR); Young Mi RYU, Suwon-si (KR)

(73) Assignee: Samsung Electro-Mechanics Co., Ltd., Suwon-si (KR)

(21) Appl. No.: 14/861,675

(22) Filed: Sep. 22, 2015

(30) Foreign Application Priority Data
Nov. 26, 2014 (KR) 10-2014-0166349

(51) Int. Cl. H01L 25/16; H01L 23/00; H01L 23/13

(52) U.S. Cl. CPC H01L 25/16; H01L 23/13; H01L 24/83; H01L 2924/014; H01L 2224/83801

(57) ABSTRACT

A semiconductor package and a method of manufacturing a semiconductor package are provided. The semiconductor package includes a first substrate having electrodes are disposed on both surfaces thereof, one or more first elements mounted on a first surface of the first substrate, a first insulating member comprising an insulating material disposed on a first surface of the first substrate and affixing one or more first elements to the first surface of the first substrate, and one or more second elements mounted on a second surface of the first substrate. At least a portion of the first elements is externally exposed from the first insulating member.

### CROSS-REFERENCE TO RELATED APPLICATION

This application claims the benefit under 35 USC 119(a) of Korean Patent Application No. 10-2014-0166349 filed on Nov. 26, 2014, in the Korean Intellectual Property Office, the entire disclosure of which is incorporated herein by reference for all purposes.

### BACKGROUND

1. Field

The present disclosure relates to a semiconductor package and a method of manufacturing the same.

2. Description of Related Art

Recently, there has been a rapid increase in market demand for portable electronic devices. Further, the miniaturization and weight reduction of electronic components mounted on electronic products are in continuous demand.

In order to miniaturize and to reduce the weight of electronic components, a system on chip (SOC) technology of implementing a plurality of individual components on a single chip, a system in package (SIP) technology of integrating a plurality of individual components in a single package, and the like, as well as technology for reducing individual sizes of mounted components are utilized.

In order to manufacture a compact, miniaturized semiconductor package, a structure in which electronic components are mounted on both surfaces of a substrate has been further developed. A double-sided mounting package is described, for example, in Japanese Patent Laid-Open Publication No. 2012-151829.

However, since a double-sided mounting package may have separation shields on both surfaces thereof, the thickness of the package is increased. As a result, the requirements of a thin electronic product have been difficult to satisfy.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor package includes a first substrate having electrodes are disposed on both surfaces thereof, one or more first elements mounted on a first surface of the first substrate, a first insulating member comprising an insulating material disposed on a first surface of the first substrate and affixing one or more first elements to the first surface of the first substrate, and one or more second elements mounted on a second surface of the first substrate, in which at least a portion of the first elements is externally exposed from the first insulating member.

The general aspect of the semiconductor package may further include a second substrate having a cavity and bonded to the other surface of the first substrate, and the one or more second elements may be housed within the cavity of the second substrate.

The first insulating member may include an insulating material coated on the one surface of the first substrate by an under-fill or side-fill method.

The second substrate may include an electrode pad forming an electrical connection with the first substrate on a first surface of the second substrate, and an external connection terminal on a second surface of the second substrate.

The general aspect of the semiconductor package may further include a pick-up tape attached to an upper surface of the one or more first elements.

The general aspect of the semiconductor package may further include an insulating layer, the insulating layer including an insulating material disposed between the first substrate and the second substrate.

The first substrate may include a blocking part for blocking flow of the insulating material.

The blocking part may be formed by a groove or a protrusion formed along an outer shape of the cavity of the second substrate.

The cavity of the second substrate may be formed in a recessed or through-hole form.

The one or more first elements and the one or more second elements may each include at least one of an electronic component, electronic element or electrical circuit element.

In another general aspect, a method of manufacturing a semiconductor package includes obtaining a first substrate having electrodes disposed on both surfaces of the first substrate, mounting one or more first elements on a first surface of the first substrate, providing an insulating material on the first surface of the first substrate such that at least a portion of the first elements is externally exposed, and bonding the second substrate to a second surface of the first substrate.

The second substrate may include a cavity having a recessed or through-hole shape.

The bonding of the second substrate may involve mounting one or more second elements on the second surface of the first substrate, and bonding the second substrate to the second surface of the first substrate such that one or more second elements are mounted within the cavity.

The bonding of the second substrate may involve coating a solder paste on the second surface of the first substrate, positioning the one or more second elements and the second substrate on the solder paste, and curing the solder paste.

The general aspect of the method may further involve attaching a pick-up tape to an upper surface of the one or more first elements mounted on the first surface of the first substrate.

The general aspect of the method may further involve, before the bonding of the second substrate to the second surface of the first substrate, turning the first substrate by use of the pick-up tape.

In another general aspect, a semiconductor package includes a first substrate, a first element disposed on a first substrate, a second substrate having a cavity therein and disposed on a side of the first substrate opposite to the first element, and a second element disposed in the cavity of the second substrate.

The general aspect of the semiconductor package may further include an insulating member disposed on the first element and partially covering the first element.

The general aspect of the semiconductor package may further include an electrode pad electrically connecting the second substrate to the first substrate, and an external connection terminal disposed on a side of the second substrate opposite the first substrate.

The second element may be electrically connected to the first substrate by solder paste, and an insulating material embeds the second element in the cavity of the second substrate.

Other features and aspects will be apparent from the following detailed description, the drawings, and the claims.

### BRIEF DESCRIPTION OF THE DRAWINGS

FIG. 1 is a perspective view illustrating an example of a semiconductor package according to the present disclosure.

FIG. 2 is a cross-sectional view illustrating an example of a semiconductor package according to the present disclosure.

FIG. 3 is an exploded perspective view of the semiconductor package according to the present disclosure.

FIG. 4 is a cross-sectional view illustrating another example of a semiconductor package according to the present disclosure.

FIGS. 5 through 9 are perspective views illustrating a method of manufacturing a semiconductor package according to the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

According to an example of the present disclosure, a double-sided mounted semiconductor package may be formed to be slim.

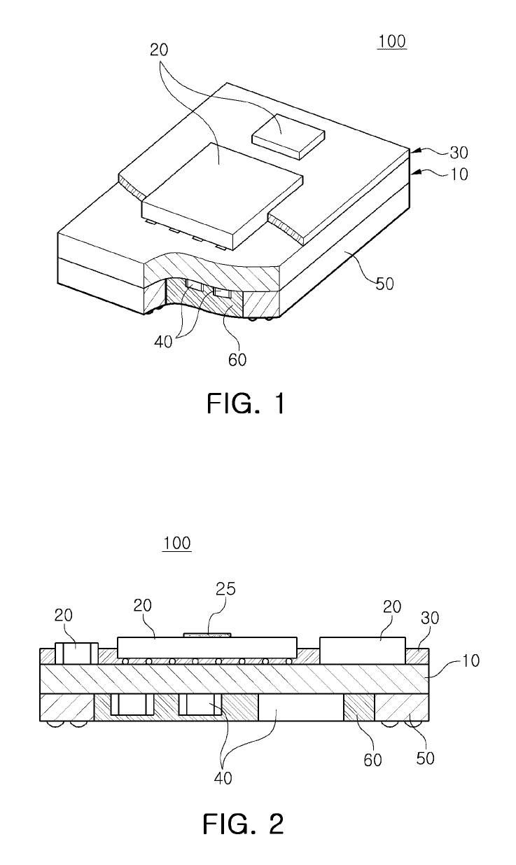

FIG. 1 is a perspective view illustrating an example of a semiconductor package according to the present disclosure.

Referring to FIG. 1, a semiconductor package 100 has one or more first elements 20 mounted on one surface of a first substrate 10, and one or more second elements 40 are mounted on the other surface of the first substrate 10. The first elements 20 and the second elements 40 may be electronic components, electronic elements, or electrical circuit elements.

In this example, the first substrate 10 has electrodes formed on both surfaces thereof, and the first elements 20 and the second elements 40 are electrically connected externally or connected to internal elements by the electrodes.

A first insulating member 30 is formed on one surface of the first substrate. The first insulating member 30 may be formed of an insulating material coated on one surface of the first substrate 10, and may fix one or more first elements 20 to one surface of the first substrate 10.

In this example, the first insulating member 30 only partially coats a region of the first elements 20. As a result, at least a portion of an overall surface area of the first elements 20 may be externally exposed from the first insulating member 30. However, in another example, the first insulating member 30 may coat the entire region of the first elements 20.

According to one example of the present disclosure, the first insulating member 30 may include an insulating material coated on one surface of the first substrate by an under-fill or side-fill method.

The first elements 20 fixed to one surface of the first substrate may not use a separation shield. For example, the first insulating member 30 may simultaneously fix the first elements 20 to the first substrate 10 and may provide insulative properties. Thus, stability against shock and circuit configuration stability may be secured without using a separation shield, and as a result, since the shield in the related art increases the thickness of the semiconductor package, the semiconductor package may easily be slimmed and used for a range of thin electronic products.

A second substrate 50 may be bonded to the other surface of the first substrate.

According to one example of the present disclosure, the second substrate 50 includes a cavity formed therein, and one or more second elements 40 are housed within the cavity of the second substrate 50. The cavity may be formed in a recessed or through-hole form.

According to the example illustrated in FIG. 1, the cavity formed in the second substrate 50 is filled with an insulating material 60.

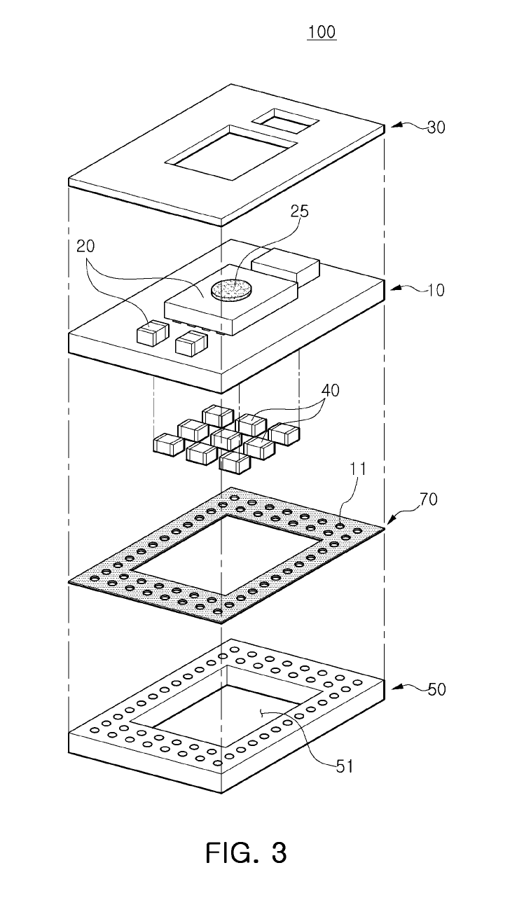

FIG. 2 is a cross-sectional view illustrating an example of the semiconductor package illustrated in FIG. 1.

Referring to FIG. 2, one or more first elements 20 may be mounted on one surface of the first substrate 10, and a first insulating member 30 formed by filling a connection part between the first elements 20 and the first substrate 10 with an insulation material may be formed on one surface of the first substrate 10. Since a thickness of the first insulating member 30 is smaller than that of the first element 20, it may be seen that at least a portion of an overall surface area of the first elements 20 may be externally exposed from the first insulating member 30.

According to one example of the present disclosure, the semiconductor package 100 includes a pick-up tape 25 attached to an upper surface of the first element 20. The pick-up tape 25 may be used to change a direction of the semiconductor package 100. For example, in order to mount the second substrate 50 on the other surface of the first substrate 10, it is required that the first substrate 10 be turned. During a manufacturing process, the first substrate 10 may be turned by using the pick-up tape 25.

According to one example, one or more second elements 40 and the second substrate 50 are mounted on the other surface of the first substrate 10, as illustrated in FIG. 2.

The second substrate 50 may have an electrode pad for forming an electrical connection with the first substrate 10 formed on one surface thereof, and an external connection terminal formed on the other surface thereof.

According to one example of the present disclosure, the second substrate 50 may be connected to an electrode of the first substrate 10, and may include the external connection terminal externally exposed to electrically connect the semiconductor package 100 to an outside source.

According to one example of the present disclosure, the second substrate 50 may have a cavity formed therein, and one or more second elements 40 may be housed within the cavity. In addition, the cavity may be filled with an insulating material 60, as illustrated in FIG. 2.

Thus, the second elements may not require a separation shield, or the like, and may still be protected from external physical shock by the second substrate 50. Although the example illustrated in FIG. 2 illustrates an example in which the second substrate 50 has a through cavity, in another example, the second substrate 50 may have a cavity in which only a portion thereof penetrates, or a non-through cavity.

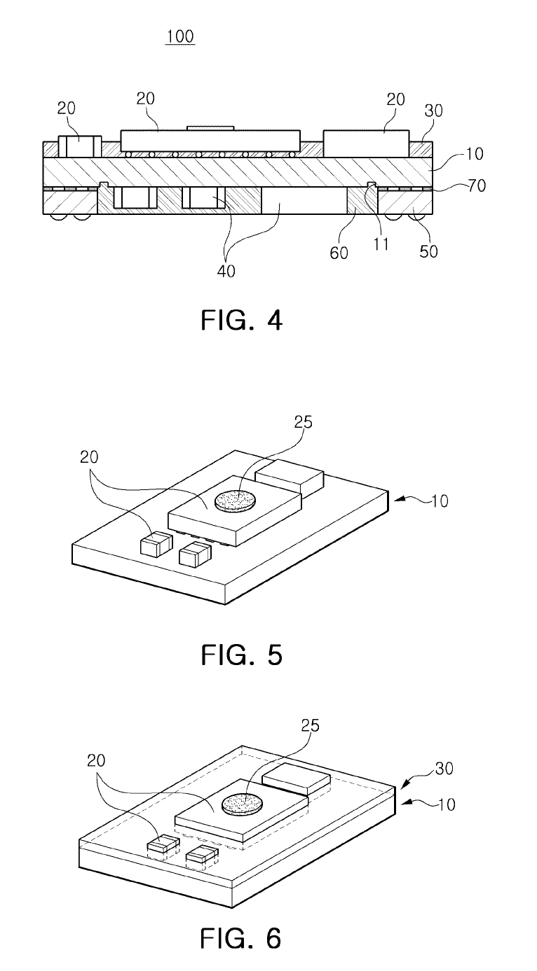

FIG. 3 is an exploded perspective view of an example of the semiconductor package described in reference to FIG. 1.

Referring to FIG. 3, the semiconductor package 100 further includes an insulating layer 70 and a blocking part 11.

The insulating layer 70 may be formed of an insulating material filled between the first substrate 10 and the second substrate 50. The insulating layer 70 may be formed of an insulating material and provided between the first substrate 10 and the second substrate 50 to protect a conductive member (e.g., a bump, or the like) electrically connecting the first substrate 10 and the second substrate 50 to each other. Alternatively, the insulating layer 70 may simultaneously insulate the first substrate 10 and the second substrate 50 from each other and improve adhesion between the first substrate 10 and the second substrate 50 to increase reliability.

The blocking part 11 may block flow of the insulating material forming the insulating layer 70. For example, the blocking part 11 may block the insulating material injected between the first substrate 10 and the second substrate 50 from flowing into the cavity 51 of the second substrate 50.

According to one example of the present disclosure, the blocking part 11 may be formed of a groove or a protrusion formed along an outer shape of the cavity 51 of the second substrate 50. Referring to the example illustrated in FIG. 3, the blocking part 11 is formed of a protrusion such that the insulating layer 70 has a perforation in the exploded perspective view.

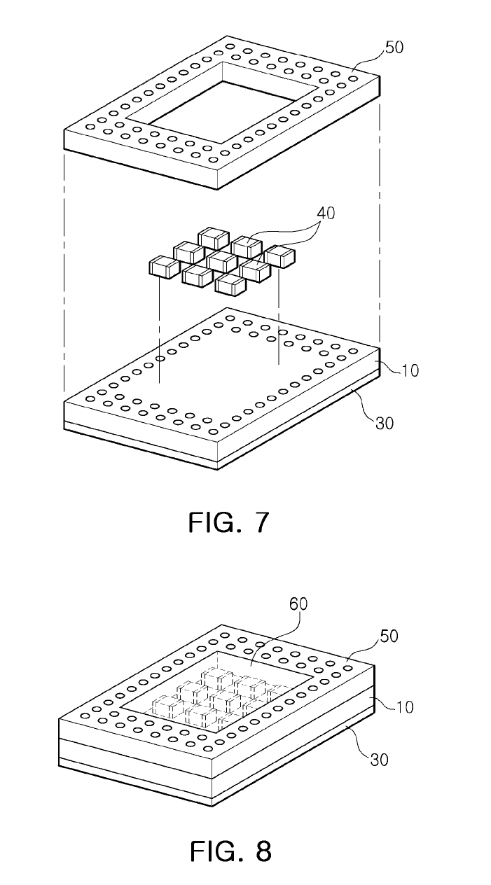

FIG. 4 is cross-sectional view illustrating another example of a semiconductor package according to the present disclosure.

Referring to the example illustrated in FIG. 4, the first elements 20, the pick-up tape 25 attached to an upper surface of the first element 20, and the first insulating member 30 fixing the first elements 20 to the first substrate 10 are formed on one surface of the first substrate 10.

The second elements 40 and the second substrate 50 may be mounted on the other surface of the first substrate 10, and the insulating layer 70 may be formed between the first substrate 10 and the second substrate 50. Since the second substrate 50 may have the cavity 51 formed therein, the second elements 40 may be housed within the cavity.

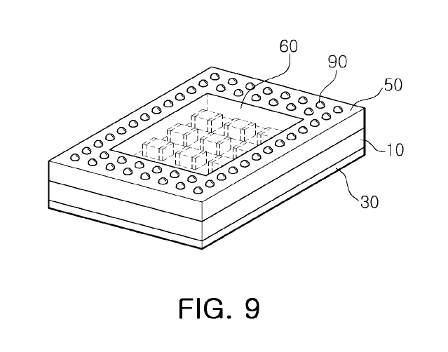

FIGS. 5 through 9 are perspective views illustrating an example of a method of manufacturing a semiconductor package according to the present disclosure.

Hereinafter, the method of manufacturing a semiconductor package will be described with reference to FIGS. 5 through 9.

First, referring to FIG. 5, the first substrate 10 on which the electrodes are formed on both surfaces thereof is prepared, and one or more first elements 20 may be mounted on one surface of the first substrate 10.

As illustrated in FIG. 5, the pick-up tape 25 may be attached to the upper surface of one or more first elements 20 mounted on one surface of the first substrate 10.

Referring to FIG. 6, the insulating material 30 is provided on one surface of the first substrate 10 so that at least a portion of the overall surface area of the first elements 20 is externally exposed.

The first substrate 10 may be turned by using the pick-up tape 25, and the second substrate 50 and the second elements 40 may then be mounted on the other surface of the first substrate 10.

Referring to FIGS. 7 and 8, the second substrate 50 includes a recessed or through-hole-shaped cavity formed therein, and the second substrate 50 may be bonded to the other surface of the first substrate 10 so that one or more elements 40 are mounted within the cavity.

According to one example of the present disclosure, in order to bond the second substrate 50 to the first substrate 10, solder paste is first coated on the other surface of the first substrate 10, and one or more elements 40 and the second substrate 50 are positioned on the solder paste. Then, the solder paste is cured to bond the second substrate 50 to the first substrate 10 with the one or more elements 40 attached to the first substrate 10.

According to the example illustrated in FIG. 9, the electrode pad for forming an electrical connection between the first substrate 10 and the second substrate 50 may be formed on one surface of the second substrate 50, and the external connection terminal 90 may be formed on the other surface of the second substrate 50. The external connection terminal 90 may be connected to the electrode on the first substrate, and may thus electrically connect the semiconductor package 100 and an external device to each other.

As set forth above, according to an example of the present disclosure, the double-sided mounted semiconductor package may be manufactured to be slim by embedding one or more elements within the semiconductor package.

In addition, according to another example of the present disclosure, an electrical connection with an external device may easily be formed by using an electrode pad externally exposed from the semiconductor package.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package comprising:
a first substrate having electrodes are disposed on both surfaces thereof;
one or more first elements mounted on a first surface of the first substrate;
a first insulating member comprising an insulating material disposed on a first surface of the first substrate and affixing one or more first elements to the first surface of the first substrate; and
one or more second elements mounted on a second surface of the first substrate,
wherein at least a portion of the first elements is externally exposed from the first insulating member.

2. The semiconductor package of claim 1, further comprising a second substrate having a cavity and bonded to the other surface of the first substrate,
wherein the one or more second elements are housed within the cavity of the second substrate.

3. The semiconductor package of claim 1, wherein the first insulating member comprises an insulating material coated on the one surface of the first substrate by an under-fill or side-fill method.

4. The semiconductor package of claim 1, wherein the second substrate comprises an electrode pad forming an electrical connection with the first substrate on a first surface of the second substrate, and an external connection terminal on a second surface of the second substrate.

5. The semiconductor package of claim 1, further comprising a pick-up tape attached to an upper surface of the one or more first elements.

6. The semiconductor package of claim 1, further comprising an insulating layer, the insulating layer comprising an insulating material disposed between the first substrate and the second substrate.

7. The semiconductor package of claim 6, wherein the first substrate includes a blocking part for blocking flow of the insulating material.

8. The semiconductor package of claim 7, wherein the blocking part is formed by a groove or a protrusion formed along an outer shape of the cavity of the second substrate.

9. The semiconductor package of claim 8, wherein the cavity of the second substrate is formed in a recessed or through-hole form.

10. The semiconductor package of claim 1, wherein the one or more first elements and the one or more second elements each comprise at least one of an electronic component, electronic element or electrical circuit element.

11. A method of manufacturing a semiconductor package, the method comprising:
obtaining a first substrate having electrodes disposed on both surfaces of the first substrate;
mounting one or more first elements on a first surface of the first substrate;
providing an insulating material on the first surface of the first substrate such that at least a portion of the first elements is externally exposed; and
bonding the second substrate to a second surface of the first substrate.

12. The method of claim 11, wherein the second substrate comprises a cavity having a recessed or through-hole shape.

13. The method of claim 12, wherein the bonding of the second substrate comprises:
mounting one or more second elements on the second surface of the first substrate; and
bonding the second substrate to the second surface of the first substrate such that one or more second elements are mounted within the cavity.

14. The method of claim 11, wherein the bonding of the second substrate comprises:
coating a solder paste on the second surface of the first substrate;
positioning the one or more second elements and the second substrate on the solder paste; and
curing the solder paste.

15. The method of claim 11, further comprising attaching a pick-up tape to an upper surface of the one or more first elements mounted on the first surface of the first substrate.

16. The method of claim 15, further comprising, before the bonding of the second substrate to the second surface of the first substrate, turning the first substrate by use of the pick-up tape.

17. A semiconductor package comprising:
a first substrate;
a first element disposed on a first substrate;
a second substrate having a cavity therein and disposed on a side of the first substrate opposite to the first element; and
a second element disposed in the cavity of the second substrate.

18. The semiconductor package of claim 17, further comprising an insulating member disposed on the first element and partially covering the first element.

19. The semiconductor package of claim 17, further comprising an electrode pad electrically connecting the second substrate to the first substrate, and an external connection terminal disposed on a side of the second substrate opposite the first substrate.

20. The semiconductor package of claim 17, wherein the second element is electrically connected to the first substrate by solder paste, and an insulating material embeds the second element in the cavity of the second substrate.
